(19) United States
(12) Patent Application Publication
(10) Pub. No.: US 2023/0077367 A1
(43) Pub. Date: Mar. 16, 2023

(54) SEMICONDUCTOR DEVICE AND MANUFACTURING METHOD THEREOF

(71) Applicant: RENESAS ELECTRONICS CORPORATION, Tokyo (JP)

(72) Inventors: Yasuhiro OKAMOTO, Ibaraki (JP); Nobuo MACHIDA, Ibaraki (JP); Koichi ARAI, Ibaraki (JP); Kenichi HISADA, Ibaraki (JP); Yasunori YAMASHITA, Ibaraki (JP); Satoshi EGUCHI, Ibaraki (JP); Hironobu MIYAMOTO, Ibaraki (JP); Atsushi SAKAI, Tokyo (JP); Katsumi EIKYU, Tokyo (JP)

(21) Appl. No.: 18/057,330

(22) Filed: Nov. 21, 2022

Related U.S. Application Data
(62) Division of application No. 16/223,839, filed on Dec. 18, 2018.

(30) Foreign Application Priority Data
Jan. 29, 2018 (JP) 2018-012427

(51) Int. Cl. H01L 29/78; H01L 29/423; H01L 29/36; H01L 29/66; H01L 21/02; H01L 21/04; H01L 29/10; H01L 29/08; H01L 29/16

(52) U.S. Cl. CPC H01L 29/7813; H01L 29/4236; H01L 29/36; H01L 29/66068; H01L 21/02378; H01L 21/02529; H01L 21/0465; H01L 21/049; H01L 21/02634; H01L 29/1095; H01L 29/0882; H01L 29/0865; H01L 21/0475; H01L 29/1608; H01L 21/0274

(57) ABSTRACT

A drift layer is formed over a semiconductor substrate which is an SiC substrate. The drift layer includes first to third n-type semiconductor layers and a p-type impurity region. Herein, an impurity concentration of the second n-type semiconductor layer is higher than an impurity concentration of the first n-type semiconductor layer and an impurity concentration of the third n-type semiconductor layer. Also, in plan view, the second semiconductor layer located between the p-type impurity regions adjacent to each other overlaps with at least a part of a gate electrode formed in a trench.

### CROSS-REFERENCE TO RELATED APPLICATION

The present application is a Divisional of U.S. patent application Ser. No. 16/223,839 filed on Dec. 18, 2018, which claims priority from Japanese Patent Application No. 2018-012427 filed on Jan. 29, 2018, the content of which is hereby incorporated by reference into this application.

### TECHNICAL FIELD OF THE INVENTION

The present invention relates to a semiconductor device and a manufacturing method thereof, and is suitably applicable to a semiconductor device using a silicon carbide (SiC) substrate.

### BACKGROUND OF THE INVENTION

In the field of the semiconductor device including a power transistor, a semiconductor device using an SiC substrate has been studied. When the SiC substrate is used, since the band gap of SiC is larger than that of silicon (Si), the dielectric breakdown voltage becomes higher. Further, in the power transistor of the SiC substrate, the trench gate structure that is used also in the power transistor of the Si substrate is applied.

Japanese Patent Application Laid-Open Publication No. 2014-175518 (Patent Document 1) discloses a power transistor having a trench gate structure using an SiC substrate, and an n-type low-concentration drift layer provided with a p-type impurity region to relax concentration of electric field and an n-type high-concentration drift layer formed on the low-concentration drift layer are disclosed. In addition, it discloses that a trench gate is provided in the high-concentration drift layer.

Japanese Patent Application Laid-Open Publication No. 2001-274395 (Patent Document 2) discloses a planar-type power transistor using an SiC substrate, and a structure in which a low-concentration epitaxial layer, a high-concentration epitaxial layer and a low-concentration epitaxial layer are stacked on a semiconductor substrate is disclosed.

Japanese Patent Application Laid-Open Publication No. 2015-26726 (Patent Document 3) discloses a power transistor having a trench gate structure using an SiC substrate, and an n-type first low-concentration drift layer provided with a p-type impurity region to relax concentration of electric field and an n-type second low-concentration drift layer formed on the first low-concentration drift layer are disclosed. In addition, providing an n-type high-concentration impurity region between a plurality of p-type impurity regions is also disclosed.

### SUMMARY OF THE INVENTION

In the power transistor having the trench gate structure using the SiC substrate, it is desired to reduce the on-resistance of the power transistor and to improve the breakdown voltage around a lower portion of the trench gate.

Other problems and novel features of the present invention will be apparent from the description of the present specification and the accompanying drawings.

The following is a brief description of an outline of a typical embodiment disclosed in the present application.

According to an embodiment, a semiconductor device includes: a semiconductor substrate configured to contain silicon and carbon; a first semiconductor layer of a first conductivity type formed over an upper surface of the semiconductor substrate; a third semiconductor layer of the first conductivity type formed over the first semiconductor layer; and a second semiconductor layer of the first conductivity type formed between the first semiconductor layer and the third semiconductor layer. The semiconductor device further includes: a first impurity region and a second impurity region which are formed between the first semiconductor layer and the third semiconductor layer, have a second conductivity type opposite to the first conductivity type, and are formed so as to interpose the second semiconductor layer in plan view; a trench formed in the third semiconductor layer; and a gate electrode buried in the trench with a gate insulating film interposed therebetween. Herein, an impurity concentration of the second semiconductor layer is higher than an impurity concentration of the first semiconductor layer and an impurity concentration of the third semiconductor layer, and the second semiconductor layer located between the first impurity region and the second impurity region overlaps with at least a part of the gate electrode in plan view.

According to an embodiment disclosed in this application, it is possible to improve the performance of the semiconductor device.

### BRIEF DESCRIPTIONS OF THE DRAWINGS

FIG. 1 is a plan view showing a layout of a semiconductor chip corresponding to a semiconductor device according to a first embodiment;

FIG. 2 is a plan view of a principal part of the semiconductor device according to the first embodiment;

FIG. 3 is a cross-sectional view of the semiconductor device according to the first embodiment;

FIG. 4 is a cross-sectional view showing a manufacturing process of the semiconductor device according to the first embodiment;

FIG. 5 is a cross-sectional view showing the manufacturing process of the semiconductor device continued from FIG. 4;

FIG. 6 is a cross-sectional view showing the manufacturing process of the semiconductor device continued from FIG. 5;

FIG. 7 is a cross-sectional view showing the manufacturing process of the semiconductor device continued from FIG. 6;

FIG. 8 is a cross-sectional view showing the manufacturing process of the semiconductor device continued from FIG. 7;

FIG. 9 is a cross-sectional view showing the manufacturing process of the semiconductor device continued from FIG. 8;

FIG. 10 is a cross-sectional view showing the manufacturing process of the semiconductor device continued from FIG. 9;

FIG. 11 is a cross-sectional view showing the manufacturing process of the semiconductor device continued from FIG. 10;

FIG. 12 is a cross-sectional view showing the manufacturing process of the semiconductor device continued from FIG. 11;

FIG. 13 is a cross-sectional view showing the manufacturing process of the semiconductor device continued from FIG. 12;

FIG. 14 is a cross-sectional view showing the manufacturing process of the semiconductor device continued from FIG. 13;

FIG. 15 is a graph chart showing a result of simulation by the inventors of the present invention;

FIG. 16 is a graph chart showing a result of simulation by the inventors of the present invention;

FIG. 17 is a graph chart showing a result of simulation by the inventors of the present invention;

FIG. 18 is a graph chart showing a result of simulation by the inventors of the present invention;

FIG. 19 is a graph chart showing a result of simulation by the inventors of the present invention;

FIG. 20 is a graph chart showing a result of simulation by the inventors of the present invention;

FIG. 21 is a graph chart showing a result of simulation by the inventors of the present invention;

FIG. 22 is a cross-sectional view of a semiconductor device according to a modification of the first embodiment;

FIG. 23 is a graph chart showing a result of simulation by the inventors of the present invention;

FIG. 24 is a plan view of a principal part of a semiconductor device according to a second embodiment;

FIG. 25 is a cross-sectional view of the semiconductor device according to the second embodiment;

FIG. 26 is a cross-sectional view of a semiconductor device according to a modification of the second embodiment;

FIG. 27 is a cross-sectional view of a semiconductor device according to a third embodiment;

FIG. 28 is a cross-sectional view showing a manufacturing process of the semiconductor device according to the third embodiment;

FIG. 29 is a cross-sectional view showing the manufacturing process of the semiconductor device continued from FIG. 28;

FIG. 30 is a cross-sectional view showing the manufacturing process of the semiconductor device continued from FIG. 29;

FIG. 31 is a cross-sectional view of a semiconductor device according to a modification of the third embodiment;

FIG. 32 is a plan view of a principal part of a semiconductor device according to a fourth embodiment;

FIG. 33 is a cross-sectional view of the semiconductor device according to the fourth embodiment;

FIG. 34 is a plan view of a principal part of a semiconductor device according to a modification of the fourth embodiment;

FIG. 35 is a cross-sectional view of the semiconductor device according to the modification of the fourth embodiment; and

FIG. 36 is a cross-sectional view showing a semiconductor device according to a studied example.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle, and the number larger or smaller than the specified number is also applicable. Further, in the embodiments described below, the constituent elements (including element steps) are not always indispensable unless otherwise stated or except the case where the constituent elements are apparently indispensable in principle. Similarly, in the embodiments described below, when the shape of the constituent elements, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments of the present invention will be described in detail with reference to drawings. Note that components having the same function are denoted by the same reference characters throughout the drawings for describing the embodiments, and the repetitive description thereof will be omitted. In addition, the description of the same or similar portions is not repeated in principle unless particularly required in the following embodiments.

Further, the size of respective portions does not correspond to that of an actual device in cross-sectional view and plan view, and a specific portion may be shown in a relatively enlarged manner in some cases so as to make the drawings easy to see. Also, even when a cross-sectional view and a plan view correspond to each other, a specific portion may be shown in a relatively enlarged manner in some case so as to make the drawings easy to see.

In addition, in some drawings used in the following embodiments, hatching is sometimes omitted even in a cross-sectional view so as to make the drawings easy to see.

### First Embodiment

Hereinafter, a structure of a semiconductor device according to the present embodiment, a manufacturing method of the semiconductor device, a modification of the present embodiment, and a main feature of the present embodiment will be described in sequence.

<Structure of Semiconductor Device>

FIG. 1 is a plan view of a semiconductor chip C corresponding to a semiconductor device according to the present embodiment. In FIG. 1, for easy understanding, a state seen through an insulating film IF5 (see FIG. 3) is shown, and hatching is applied to a gate potential electrode GE and a source potential electrode SE though FIG. 1 is a plan view. The semiconductor chip C has a plurality of power transistors having a trench gate structure. The power transistor like this is referred to as a power MOSFET (Metal Oxide Semiconductor Field Effect Transistor) in some cases.

As shown in FIG. 1, a front surface of the semiconductor chip C is mainly covered with the source potential electrode SE and the gate potential electrode GE. A part of the gate potential electrode GE is formed in an outer circumference of the source potential electrode SE in a pad region PA which is a region near a central part of the semiconductor chip C, and a part of the source potential electrode SE is formed in an outer circumference of the part of the gate potential electrode GE. In the pad region PA, a part of the insulating film IF5 is removed, and a part of the source potential electrode SE and a part of the gate potential electrode GE are exposed. By connecting an external connection terminal such as a wire bonding or a clip (copper plate) to each of these exposed source potential electrode SE and gate potential electrode GE, the semiconductor chip C is electrically connected to another chip, a wiring board or the like.

FIG. 2 is a plan view of a principal part of the semiconductor chip C and corresponds to a plan view showing a part below the source potential electrode SE in the pad region PA in FIG. 1. FIG. 3 is a cross-sectional view taken along a line A-A in FIG. 2.

FIG. 2 shows only a gate electrode G formed in a trench TR, an n-type semiconductor layer NE2, and a p-type impurity region PT which are the configuration closely related to the main feature of the present embodiment, and illustration of the other configuration is omitted. Also, the gate electrode G formed in the trench TR is indicated by broken lines, and hatching is applied to the gate electrode G formed in the trench TR so as to make the drawing easy to see though FIG. 2 is a plan view.

As shown in FIG. 2, each of the trench TR, the gate electrode G, the n-type semiconductor layer NE2, and the p-type impurity region PT extends in a Y direction. Namely, the planar shape of each of the trench TR, the gate electrode G, the n-type semiconductor layer NE2, and the p-type impurity region PT is a rectangular shape having a long side in the Y direction, and a length thereof in the Y direction is longer than that in an X direction. In addition, the trench TR, the gate electrode G, the n-type semiconductor layer NE2, and the p-type impurity region PT are arranged repeatedly in the X direction. Further, in the present embodiment, when a center line is drawn in a thickness direction (Z direction) from the center of the gate electrode G in a cross-section perpendicular to the Y direction, the two p-type impurity regions PT adjacent to each other in the X direction are arranged to be symmetrical with respect to the center line.

Although described in detail later, as one feature of the present embodiment, at least of a part of the gate electrode G formed in the trench TR is arranged at a position overlapping with the n-type semiconductor layer NE2 in plan view.

Next, a cross-sectional structure of the power transistor having the trench gate structure according to the present embodiment will be described with reference to FIG. 3.

A semiconductor substrate SB used in the present embodiment is a substrate configured to contain silicon and carbon, and is specifically a silicon carbide (SiC) substrate into which an n-type impurity is introduced. A drift layer DR is formed over an upper surface (first surface) of the semiconductor substrate SB, and a drain potential electrode DE made of a metal film is formed over a back surface (second surface) of the semiconductor substrate SB. The semiconductor substrate SB and the drift layer DR each constitute a part of the drain region of the power transistor and are electrically connected to the drain potential electrode DE, so that a drain potential is applied thereto through the drain potential electrode DE during an operation of the power transistor.

The drift layer DR includes the n-type semiconductor layers NE1 to NE3 and the p-type impurity region PT. The n-type semiconductor layer NE1 is formed over the semiconductor substrate SB, the n-type semiconductor layer NE3 is formed over the n-type semiconductor layer NE1, and the n-type semiconductor layer NE2 is formed between the n-type semiconductor layer NE1 and the n-type semiconductor layer NE3. Each of the n-type semiconductor layers NE1 to NE3 is a semiconductor layer formed by the epitaxial method on the semiconductor substrate SB which is an SiC substrate. Therefore, each of the n-type semiconductor layers NE1 to NE3 is made of SiC. Further, an impurity concentration of the n-type semiconductor layer NE2 is higher than an impurity concentration of the n-type semiconductor layer NE1 and an impurity concentration of the n-type semiconductor layer NE3. Further, the impurity concentration of the n-type semiconductor layer NE1 is almost the same as the impurity concentration of the n-type semiconductor layer NE3.

A plurality of the p-type impurity regions PT are formed between the n-type semiconductor layer NE3 and the n-type semiconductor layer NE1. The n-type semiconductor layer NE2 is formed between the p-type impurity regions PT adjacent to each other. Namely, in plan view, the p-type impurity regions PT adjacent to each other are formed so as to interpose the n-type semiconductor layer NE2. As will be described later in detail, a thickness of the p-type impurity region PT may be the same as a thickness of the n-type semiconductor layer NE2, or may be larger or smaller than the thickness of the n-type semiconductor layer NE2. In the present embodiment, the case where the thickness of the p-type impurity region PT is smaller than the thickness of the n-type semiconductor layer NE2 and the p-type impurity region PT is formed in the n-type semiconductor layer NE2 is exemplified. Therefore, in FIG. 3, the n-type semiconductor layer NE2 is formed between the p-type impurity region PT and the n-type semiconductor layer NE1.

A p-type channel region (impurity region) PC is formed on a front surface side of the n-type semiconductor layer NE3 which is an upper layer of the drift layer DR, and an n-type source region (impurity region) NS and a p-type body region (impurity region) PB are formed on a front surface side of the channel region PC. The source region NS and the body region PB are each electrically connected to the source potential electrode SE, and a source potential is applied thereto through the source potential electrode SE during the operation of the power transistor. The body region PB is provided for the purpose of reducing a contact resistance when the source potential electrode SE is connected to the channel region PC. Therefore, an impurity concentration of the body region PB is higher than an impurity concentration of the channel region PC.

In addition, a silicide layer may be formed on a front surface of the source region NS and the body region PB for the purpose of further reducing the contact resistance with the source potential electrode SE. The silicide layer is made of, for example, titanium silicide, (TiSi₂), cobalt silicide (CoSi₂) or nickel silicide (NiSi). In the present embodiment, illustration of the silicide layer is omitted.

A trench TR is formed on a front surface side of the semiconductor substrate SB. The trench TR is formed to penetrate the source region NS and the channel region PC and reach the n-type semiconductor layer NE3. Namely, a bottom of the trench TR is located in the n-type semiconductor layer NE3. Also, the trench TR is formed to be located between the two source regions NS.

The gate electrode G is buried in the trench TR with a gate insulating film GI interposed therebetween. The gate electrode G is electrically connected to the gate potential electrode GE, and a gate potential is applied thereto during the operation of the power transistor. The gate insulating film GI is, for example, a silicon oxide film, and the gate electrode G is, for example, a polycrystalline silicon film to which an n-type impurity is introduced. In addition, as the gate insulating film GI, a high dielectric constant film such as an aluminum oxide film or a hafnium oxide film having a dielectric constant higher than that of a silicon oxide film may be used instead of a silicon oxide film.

Herein, a relationship between the p-type impurity region PT and the gate electrode G in the trench TR will be described. The region near the bottom of the gate electrode G (the bottom of the trench TR) in the trench TR, in particular, near a corner of the trench TR is a region where a strong electric field is generated during the operation of the power transistor and breakage of the gate insulating film GI is likely to occur. The p-type impurity region PT is provided mainly for relaxing this electric field. Since the electric field is relaxed by providing the p-type impurity region PT in the drift layer DR below the trench TR, the breakage of the gate insulating film GI can be suppressed and the breakdown voltage of the entire drift layer DR can be improved.

Also, in the present embodiment, when a center line is drawn in the thickness direction from the center of the gate electrode G in the cross-section perpendicular to the Y direction, the two p-type impurity regions PT adjacent to each other in the X direction are arranged to be symmetrical with respect to the center line.

In addition, as described above, at least a part of the gate electrode G formed in the trench TR is located at a position overlapping with the n-type semiconductor layer NE2 in plan view. In other words, the n-type semiconductor layer NE2 is formed just below at least a part of the gate electrode G formed in the trench TR in cross-sectional view. In the present embodiment, the n-type semiconductor layer NE2 is formed just below the entire bottom connecting the two corners of the gate electrode G formed in the trench TR.

“Just below” expressed in the present embodiment means the lower side of one object, and includes a state in which one object and the other object are not physically in direct contact with each other. In other words, “just below” means a state in which one object and the other object overlap in plan view. For example, in FIG. 3, the n-type semiconductor layer NE2 is formed on the lower side of the trench TR and the gate electrode G and is not physically in direct contact with the trench TR and the gate electrode G.

A part of the gate insulating film GI is formed on the source region NS, and the interlayer insulating film IL made of, for example, silicon oxide is formed on each upper surface of the part of the gate insulating film GI and the gate electrode G. Further, a contact hole CH is formed in the interlayer insulating film IL. The contact hole CH is formed to penetrate the interlayer insulating film IL and the gate insulating film GI and reach the source region NS and the body region PB.

The source potential electrode SE is formed on the interlayer insulating film IL and the source potential electrode SE is buried in the contact hole CH. Namely, the source potential electrode SE is electrically connected to the source region NS and the body region PB. The source potential electrode SE is made of, for example, a conductive film containing aluminum as a main component. Further, the source potential electrode SE may be a stacked film of a barrier metal film made of, for example, titanium nitride and a conductive film containing aluminum as a main component. Note that, though not shown in FIG. 3, the gate potential electrode GE shown in FIG. 1 is also formed in the same manner as the source potential electrode SE, and the gate potential electrode GE is electrically connected to the gate electrode G.

The insulating film IF5 made of resin such as polyimide is formed on the source potential electrode SE. Though not shown in FIG. 3, in the pad region PA shown in FIG. 1, openings are formed in the insulating film IF5 so as to expose a part of the source potential electrode SE and a part of the gate potential electrode GE.

In addition, the region surrounded by broken lines in FIG. 3 indicates a unit cell UC. In the present embodiment, the unit cell UC includes one gate electrode G, the source region NS, the body region PB, and the channel region PC formed on each of the both sides of one gate electrode G, the drift layer DR, and the semiconductor substrate SB. In the present embodiment, the unit cell UC is defined as a region ranging from the center of the body region PB formed on one side of the gate electrode G to the center of the body region PB formed on the other side of the gate electrode G. A plurality of the unit cells UC are repeatedly formed in the semiconductor chip C.

Also, in FIG. 3, a width of the unit cell UC is represented as a distance L6. Distances L1 to L5 will be used later when describing the main feature of the present embodiment.

In the present embodiment, the distance L6 corresponding to the width of the unit cell UC is represented as a distance connecting the centers of the two body regions PB described above. Alternatively, for example, when a center line is drawn from the center of the gate electrode G in the thickness direction in the cross-section perpendicular to the Y direction, the distance connecting the center lines of the two gate electrodes adjacent in the X direction can also be represented as the distance L6.

<Manufacturing Method of Semiconductor Device>

Hereinafter, a manufacturing method of a semiconductor device according to the present embodiment will be described with reference to FIGS. 4 to 14. In FIGS. 4 to 14, for simplicity of description, only the region corresponding to the unit cell UC of FIG. 3 is shown.

First, as shown in FIG. 4, the semiconductor substrate SB made of SiC on which an epitaxial layer is formed is prepared. The epitaxial layer is a semiconductor layer made of SiC and has a single layer structure of the n-type semiconductor layer NE1 to which an n-type impurity is introduced or a stacked layer structure of the n-type semiconductor layer NE1 and the n-type semiconductor layer NE2 to which an n-type impurity is introduced. Herein, the impurity concentration of the n-type semiconductor layer NE2 is higher than the impurity concentration of the n-type semiconductor layer NE1. The n-type semiconductor layer NE1 has an impurity concentration of, for example, about 1×10¹⁶/cm³ and a thickness of about 8.6 μm. The n-type semiconductor layer NE2 has an impurity concentration of, for example, about 4×10¹⁶/cm³ and a thickness of about 0.4 μm.

The n-type semiconductor layer NE1 is formed by epitaxially growing the layer while introducing an n-type impurity to the upper surface of the semiconductor substrate SB. The n-type semiconductor layer NE2 is formed by epitaxially growing the layer while introducing an n-type impurity to the upper surface of the n-type semiconductor layer NE1 or ion-implanting an n-type impurity to a front surface of the n-type semiconductor layer NE1.

FIG. 5 shows a forming process of the p-type impurity region PT.

First, an insulating film IF1 made of, for example, silicon oxide is formed over the n-type semiconductor layer NE2 by, for example, CVD (Chemical Vapor Deposition) method. Next, the insulating film IF1 is patterned by the photolithography method and the etching process. Next, by performing ion implantation with using the patterned insulating film IF1 as a mask, the p-type impurity region PT is formed in the n-type semiconductor layer NE2. Aluminum (Al) ions are used for the ion implantation, and the ion implantation is performed under the conditions of the implantation energy of about 150 KeV and the dose amount of about 5×10¹³/cm².

Also, the thickness of the p-type impurity region PT may be the same as the thickness of the n-type semiconductor layer NE2, or may be larger or smaller than the thickness of the n-type semiconductor layer NE2. In the present embodiment, the case where the thickness of the p-type impurity region PT is smaller than the thickness of the n-type semiconductor layer NE2 and the p-type impurity region PT is formed in the n-type semiconductor layer NE2 is exemplified.

Thereafter, the insulating film IF1 is removed by, for example, the wet etching process using solution containing hydrofluoric acid.

FIG. 6 shows a forming process of the n-type semiconductor layer NE3.

The n-type semiconductor layer NE3 is formed by epitaxially growing the layer while introducing an n-type impurity to the upper surfaces of the n-type semiconductor layer NE2 and the p-type impurity region PT. The impurity concentration of the n-type semiconductor layer NE3 is lower than the impurity concentration of the n-type semiconductor layer NE2, and is almost the same as the impurity concentration of the n-type semiconductor layer NE1. The n-type semiconductor layer NE3 has the impurity concentration of, for example, about 1×10¹⁶/cm³ and the thickness of about 3.0 μm.

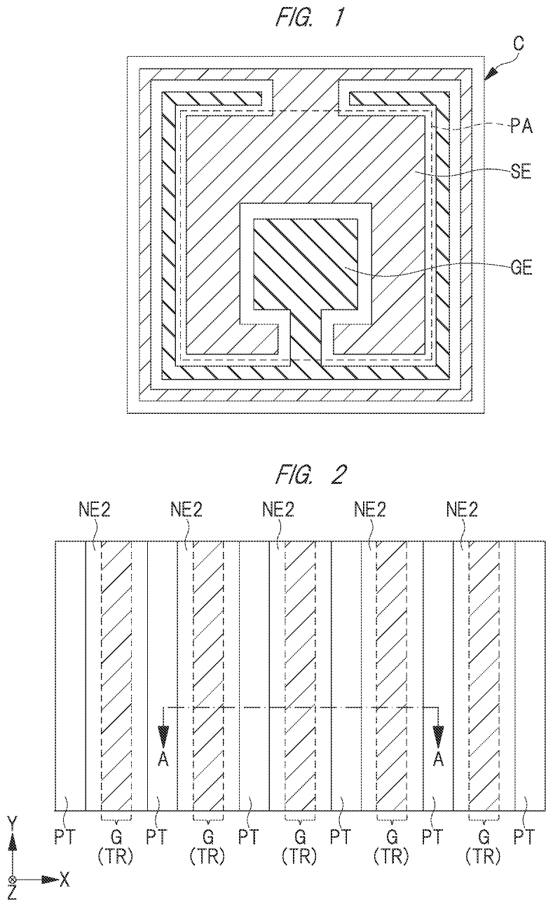

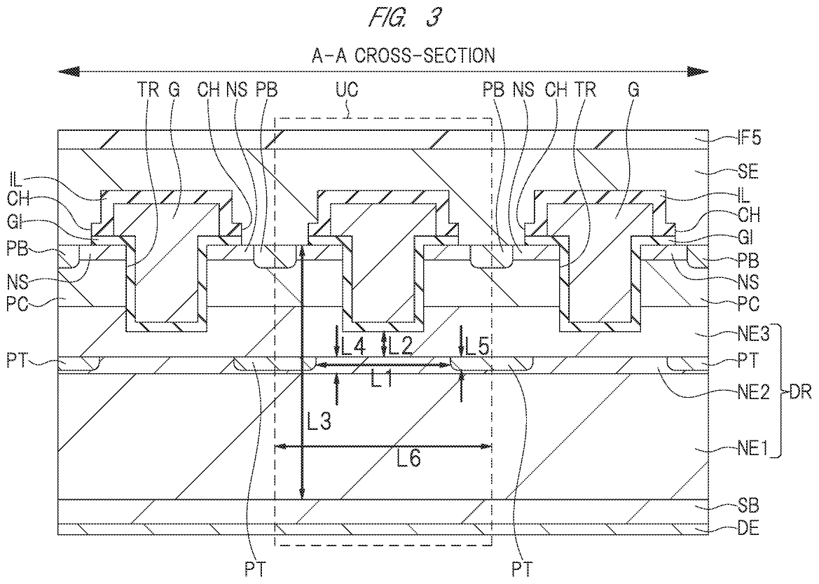

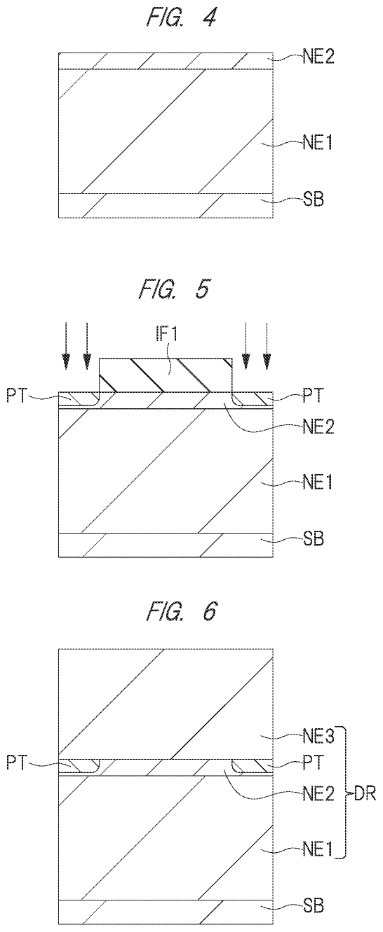

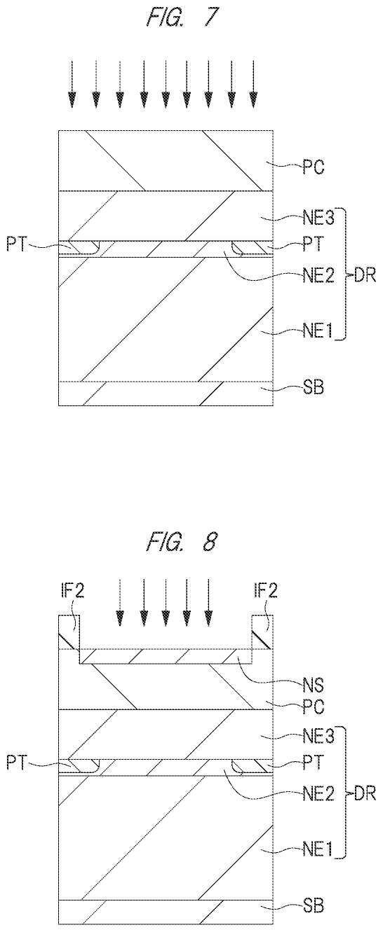

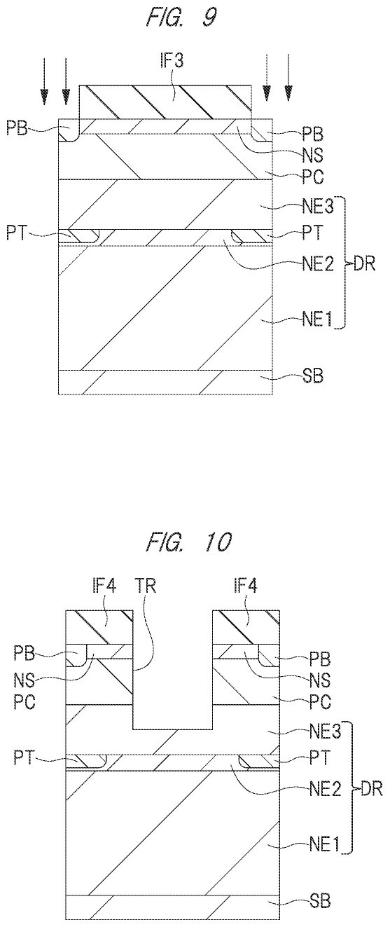

FIG. 7 shows a forming process of the p-type channel region PC.

The p-type channel region PC is formed in the n-type semiconductor layer NE3 by, for example, the ion implantation using aluminum (Al) ions.

FIG. 8 shows a forming process of the n-type source region NS.

First, an insulating film IF2 made of, for example, silicon oxide is formed over the p-type impurity region PT by, for example, the CVD method. Next, the insulating film IF2 is patterned by the photolithography method and the etching process. Then, by performing ion implantation using nitrogen (N) ions with using the patterned insulating film IF2 as a mask, the n-type source region NS is selectively formed in the p-type impurity region PT.

Thereafter, the insulating film IF2 is removed by, for example, the wet etching process using solution containing hydrofluoric acid.

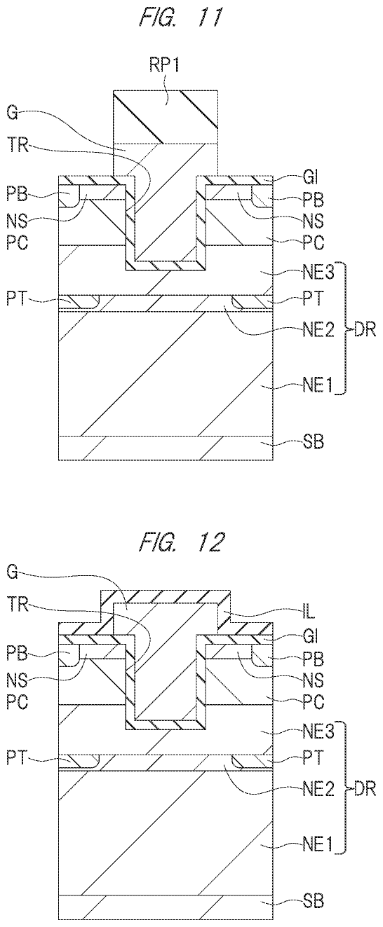

FIG. 9 shows a forming process of the p-type body region PB.

First, an insulating film IF3 made of, for example, silicon oxide is formed over the source region NS by, for example, the CVD method. Next, the insulting film IF3 is patterned by the photolithography method and the etching process. Then, by performing ion implantation using aluminum (Al) ions with using the patterned insulating film IF3 as a mask, the p-type body region PB that is adjacent to the source region NS and reaches the channel region PC is formed.

Thereafter, the insulating film IF3 is removed by, for example, the wet etching process using solution containing hydrofluoric acid.

FIG. 10 shows a forming process of the trench TR.

First, an insulating film IF4 made of, for example, silicon oxide is formed over the source region NS and the body region PB by, for example, the CVD method. Next, the insulting film IF4 is patterned by the photolithography method and the etching process. Then, by performing dry etching process with using the patterned insulating film IF4 as a mask, the trench TR that penetrates the source region NS and the channel region PC and reaches the n-type semiconductor layer NE3 is formed. A width of the trench TR is about 0.8 μm and a depth of the trench TR is about 1.2 μm. Note that the dry etching process is performed using gas made of molecules containing fluorine such as CF₄ or SF₆.

Thereafter, the insulating film IF4 is removed by, for example, the wet etching process using solution containing hydrofluoric acid.

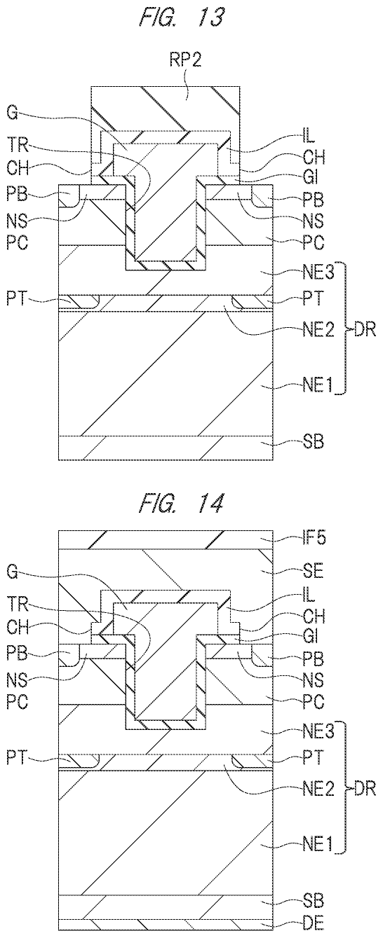

FIG. 11 shows a forming process of the gate insulating film GI and the gate electrode G.

First, the gate insulating film GI made of, for example, silicon oxide is formed in the trench TR and on the source region NS and the body region PB by, for example, the CVD method. As the gate insulating film GI, a high dielectric constant film such as an aluminum oxide film or a hafnium oxide film having a dielectric constant higher than that of a silicon oxide film may be used instead of a silicon oxide film.

Next, a conductive film made of, for example, polycrystalline silicon is formed by, for example, the CVD method over the gate insulating film GI so as to fill the trench TR. Then, a resist pattern RP1 is formed on the conductive film so as to cover a part of the conductive film. Thereafter, by performing dry etching process with using the resist pattern RP1 as a mask, the conductive film exposed from the resist pattern RP1 is removed. In this manner, the gate electrode G made of the remaining conductive film is formed.

Thereafter, the resist pattern RP1 is removed by ashing process or the like.

FIG. 12 shows a forming process of the interlayer insulating film IL.

The interlayer insulating film IL made of, for example, silicon oxide is formed over the gate insulating film GI by, for example, the CVD method so as to cover the side surface and the upper surface of the gate electrode G formed outside the trench TR. The interlayer insulating film IL is not limited to a silicon oxide film, and may be formed of other insulating film such as a silicon nitride film or a silicon oxynitride film.

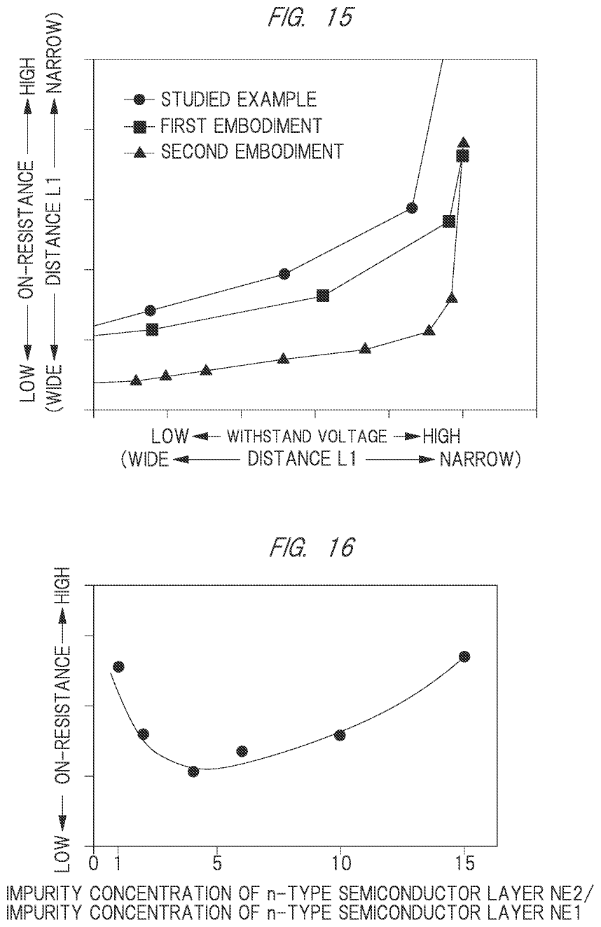

FIG. 13 shows a forming process of the contact hole CH.

First, a resist pattern RP2 that covers a part of the interlayer insulating film IL and has a width larger than the width of the gate electrode G outside the trench TR is formed over the interlayer insulating film IL. Next, by performing dry etching process with using the resist pattern RP2 as a mask, the interlayer insulating film IL and the gate insulating film GI are removed. In this manner, the contact hole CH that reaches a part of the source region NS and the body region PB is formed in the interlayer insulating film IL and the gate insulating film GI.

Thereafter, the resist pattern RP2 is removed by ashing process or the like.

In addition, though not shown in the present embodiment, a silicide layer may be formed on each upper surface of a part of the source region NS and the body region PB after the forming process of the contact hole CH. In this case, the silicide layer can be formed as follows. First, a metal film for forming a silicide layer made of, for example, titanium (Ti), cobalt (Co), or nickel (Ni) is formed on each upper surface of a part of the source region NS and the body region PB. Next, heat treatment is performed to the metal film to cause a material constituting a part of the source region NS and the body region PB to react with the metal film, thereby forming the silicide layer made of, for example, titanium silicide (TiSi₂), cobalt silicide (CoSi₂), or nickel silicide (NiSi). Thereafter, the unreacted metal film is removed.

FIG. 14 shows a forming process of the source potential electrode SE, the insulating film IF5, and the drain potential electrode DE.

First, a conductive film containing aluminum as a main component is formed over the interlayer insulating film IL by, for example, the sputtering so as to fill the contact hole CH. Next, the conductive film is patterned by the photolithography method and the etching process, so that the source potential electrode SE electrically connected to the source region NS and the body region PB is formed. Also, by forming a barrier metal film made of, for example, titanium nitride before forming the conductive film, the source potential electrode SE may be formed as a stacked film of the barrier metal film and the conductive film described above. Though not shown here, the gate potential electrode GE shown in FIG. 1 is also formed in the same manner as the source potential electrode SE, and the gate potential electrode GE is electrically connected to the gate electrode G.

Next, the insulating film IF5 made of resin such as polyimide is formed over the source potential electrode SE by, for example, the coating method. Thereafter, though not shown here, in the pad region PA shown in FIG. 1, openings are formed in the insulating film IF5 so as to expose a part of the source potential electrode SE and a part of the gate potential electrode GE.

Next, a polishing process is performed to the back surface of the semiconductor substrate SB to thin the semiconductor substrate SB to a desired thickness. Then, the drain potential electrode DE made of a metal film such as a titanium nitride film is formed over the back surface of the semiconductor substrate SB by, for example, the sputtering method or the CVD method.

In the manner described above, the semiconductor device shown in FIG. 3 is manufactured.

<Description of Studied Example>

A semiconductor device according to a studied example that the inventors of the present invention have studied will be described with reference to FIG. 36.

The semiconductor device according to the studied example is a power transistor having a trench gate structure using the semiconductor substrate SB made of SiC as in the semiconductor device according to the present embodiment. FIG. 36 is a cross-sectional view corresponding to the unit cell UC of the present embodiment. As shown in FIG. 36, in the studied example, the n-type semiconductor layer NE1, the n-type semiconductor layer NE3, and the p-type impurity region PT are formed in the region to be the drift layer DR as in the present embodiment, but the n-type semiconductor layer NE2 is not formed unlike the present embodiment.

Hereinafter, a problem in the studied example will be described.

As described above, the p-type impurity region PT is provided to relax concentration of the electric field generated near the bottom of the gate electrode G in the trench TR (the bottom of the trench TR), in particular, near the corner of the trench TR. When the width of the p-type impurity region PT is increased, the effect of relaxing concentration of electric field is further strengthened, so that the breakdown voltage of the entire drift layer DR can be improved. However, when the distance between the p-type impurity regions PT adjacent to each other is narrowed, the current path is narrowed. As a result, a problem of the increase in the on-resistance arises.

For example, the increase in the on-resistance can be suppressed by increasing the impurity concentration of the n-type semiconductor layer NE3, but this causes the deterioration of the breakdown voltage at the corner of the trench TR where the electric field concentration becomes strongest. Similarly, the on-resistance can be reduced also by increasing the impurity concentration of the n-type semiconductor layer NE1, but this decreases the breakdown voltage of the entire drift layer DR. In particular, when the n-type semiconductor layer NE1 which is the thickest layer in the drift layer DR is made to have a high concentration, the influence of the decrease in the breakdown voltage becomes larger. As described above, there is a trade-off relationship between the improvement in the breakdown voltage of the power transistor and the reduction in the on-resistance, and there is a problem that it is difficult to simultaneously achieve both of them.

<Main Feature of Semiconductor Device of Present Embodiment>

Hereinafter, the main feature and effect of the semiconductor device according to the present embodiment will be described with reference to FIGS. 15 to 21. FIGS. 15 to 21 are graph charts each showing a result of simulation by the inventors of the present invention. FIG. 15 shows not only the result of the present embodiment but also the result of the above-described studied example and the result of a second embodiment described later as comparative objects.

The distance L1 shown in FIG. 15 corresponds to the distance L1 shown in FIG. 3, and is a distance between the p-type impurity regions PT adjacent to each other. Namely, the distance L1 is a distance between each of the p-type impurity regions PT in the X direction in plan view.

The vertical axis of FIG. 15 represents a relative value of the on-resistance of the power transistor, and shows that the on-resistance is reduced and improved as the distance L1 becomes larger. The horizontal axis of FIG. 15 represents a relative value of the breakdown voltage of the power transistor, and shows that the breakdown voltage becomes higher and is improved as the distance L1 becomes narrower.

As can be seen from FIG. 15, the semiconductor device of the present embodiment is superior to the semiconductor device of the studied example in both of the on-resistance and the breakdown voltage of the power transistor.

Herein, the increase in the distance L1 means the reduction in the width of the p-type impurity region PT itself or the increase in the width of the n-type semiconductor layer NE2 formed between the p-type impurity regions PT adjacent to each other. Conversely, the reduction in the distance L1 means the increase in the width of the p-type impurity region PT itself or the reduction in the width of the n-type semiconductor layer NE2.

In the present embodiment, unlike the studied example, the n-type semiconductor layer NE2 which is a high-concentration impurity region is formed between the p-type impurity regions PT adjacent to each other. Namely, since the n-type semiconductor layer NE2 having a low resistance is formed in the region to be the current path, it is possible to reduce the on-resistance of the power transistor. In addition, the bottom of the trench TR is located in the n-type semiconductor layer NE3 whose concentration is lower than that of the n-type semiconductor layer NE2. Therefore, it is possible to improve the breakdown voltage near the bottom of the trench TR.

Further, the n-type semiconductor layer NE2 is formed just below at least a part of the gate electrode G formed in the trench TR. Therefore, the low-resistance n-type semiconductor layer NE2 is formed in the shortest path of the current path passing through the drain potential electrode DE, the channel region PC on the side surface of the trench TR (the side surface of the gate electrode G), and the source potential electrode SE. In other words, the low-resistance n-type semiconductor layer NE2 is formed in the region where the current density is high. Accordingly, it is possible to efficiently reduce the on-resistance of the power transistor.

As shown in FIG. 15, the width of the n-type semiconductor layer NE2 changes depending on the value of the distance L1, but it is important that the n-type semiconductor layer NE2 is formed just below at least a part of the gate electrode G formed in the trench TR. In other words, at least a part of the gate electrode G formed in the trench TR overlaps with the n-type semiconductor layer NE2 in plan view. In particular, it is preferable that the n-type semiconductor layer NE2 is formed just below at least one of the two corners of the gate electrode G formed in the trench TR.

As described above, the on-resistance of the power transistor can be reduced and the breakdown voltage can be improved in the present embodiment. Therefore, it is possible to improve the performance of the semiconductor device and improve the reliability of the semiconductor device.

FIGS. 16 to 21 show the result of studies by the inventors of the present invention on the relationship between the respective components in the semiconductor device of the present embodiment.

FIG. 16 shows a relationship between the ratio of the impurity concentration of the n-type semiconductor layer NE2 to the impurity concentration of the n-type semiconductor layer NE1 and the on-resistance. Herein, at each measurement point, the distance L1 is adjusted such that the breakdown voltage is constant at 1500 V. Also, the leftmost point (the point where the value of the horizontal axis is 1) is the point corresponding to the studied example.

As shown in FIG. 16, when the concentration of the n-type semiconductor layer NE2 is increased, the on-resistance is reduced. However, when the concentration of the n-type semiconductor layer NE2 is excessively increased, the on-resistance increases conversely. Namely, since the breakdown voltage decreases when the concentration of the n-type semiconductor layer NE2 is excessively increased, it is necessary to reduce the distance L1 in order to keep the breakdown voltage at 1500 V as described above. Therefore, the current path which is the region between the p-type impurity regions PT adjacent to each other becomes too narrow, so that the on-resistance eventually increases.

In the present embodiment, the range where the value of the horizontal axis is 2 to 10 can be used as an appropriate range. Also, the value of the horizontal axis is more preferably in the range of 3 to 7. For example, when the impurity concentration of the n-type semiconductor layer NE1 is about 1×10¹⁶/cm³, the impurity concentration of the n-type semiconductor layer NE2 is preferably in the range of 2×10¹⁶/cm³ to 1×10¹⁶/cm³, and most preferably in the range of 3×10¹⁶/cm³ to 7×10¹⁶/cm³.

FIG. 17 shows a relationship between the ratio of the impurity concentration of the n-type semiconductor layer NE2 to the impurity concentration of the n-type semiconductor layer NE3 and the breakdown voltage. Herein, at each measurement point, the distance L1 is adjusted such that the on-resistance is constant, and the measurement is performed under the condition that the impurity concentration of the n-type semiconductor layer NE1 and the impurity concentration of the n-type semiconductor layer NE3 are almost the same.

As can be seen from FIG. 17, the sufficient breakdown voltage of about 1500 V can be obtained in the range where the value of the horizontal axis is 2.0 to 5.0.

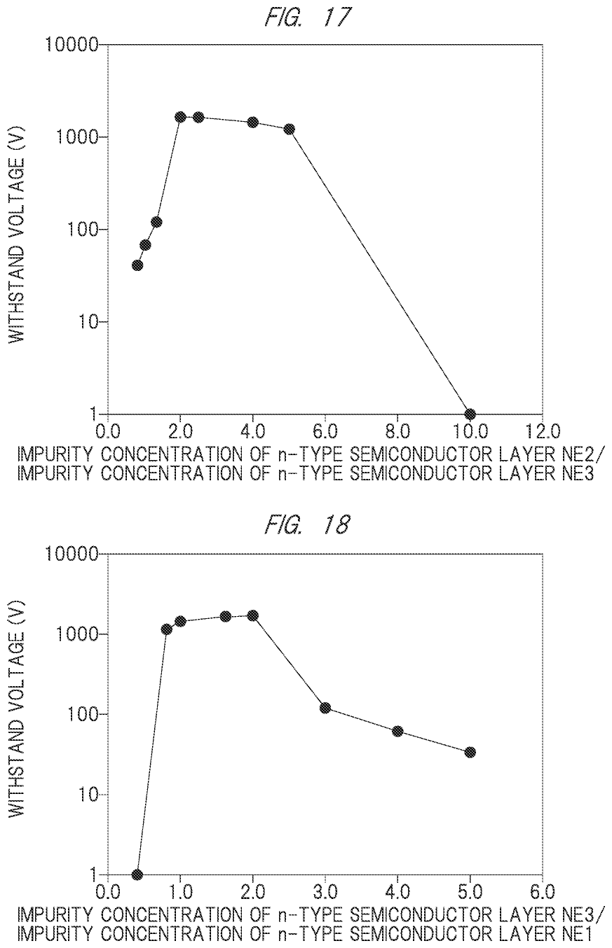

FIG. 18 shows a relationship between the ratio of the impurity concentration of the n-type semiconductor layer NE3 to the impurity concentration of the n-type semiconductor layer NE1 and the breakdown voltage. Herein, at each measurement point, the distance L1 is adjusted such that the on-resistance is constant, and the measurement is performed under the condition that the ratio of the impurity concentration of the n-type semiconductor layer NE2 to the impurity concentration of the n-type semiconductor layer NE1 is 4.

As can be seen from FIG. 18, the sufficient breakdown voltage of about 1500 V can be obtained in the range where the value of the horizontal axis is 0.8 to 2.0.

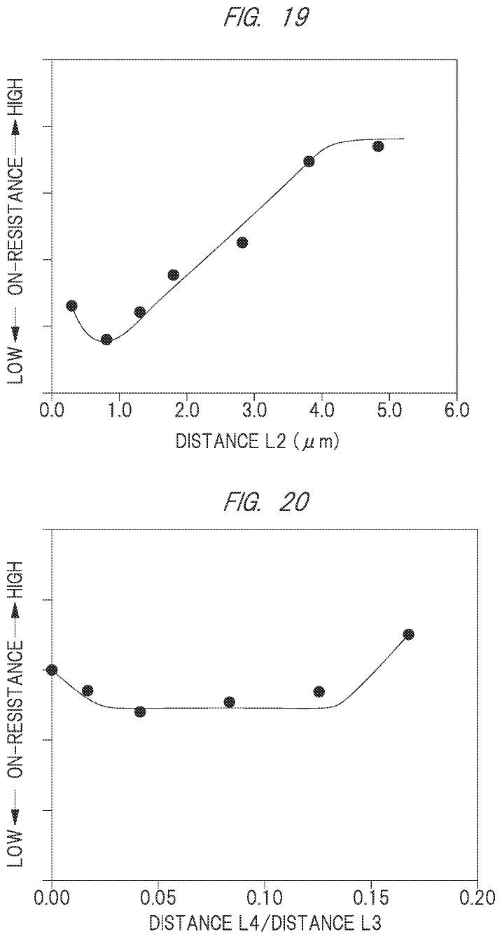

FIG. 19 shows a relationship between the distance L2 from the bottom of the trench TR to the upper surface of the n-type semiconductor layer NE2 and the on-resistance. Also, the distance L2 shown in FIG. 19 corresponds to the distance L2 shown in FIG. 3. Herein, at each measurement point, the distance L1 is adjusted such that the breakdown voltage is constant at 1500 V.

As shown in FIG. 19, when the distance L2 is 4 μm or more, the on-resistance is almost constant, but the on-resistance decreases when the distance L2 is 4 μm or less. When the distance L2 is 0.5 μm or less, the trench TR and the p-type impurity region PT come too close to each other, and the current path becomes too narrow, so that the on-resistance is increased.

In the present embodiment, the range where the distance L2 is 0.3 μm to 4.0 μm can be used as an appropriate range. In particular, the distance L2 is preferably in the range of 0.3 μm to 2.0 μm, and is most preferably in the range of 0.5 μm to 1.0 μm.

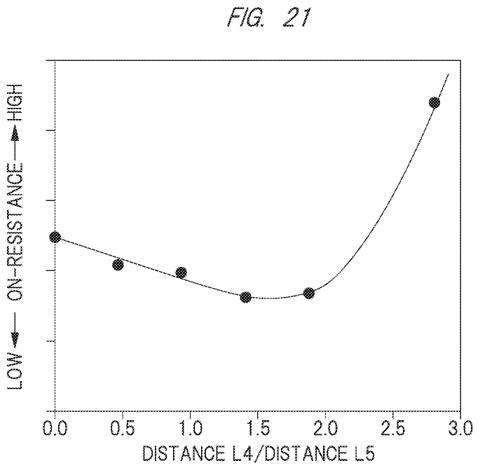

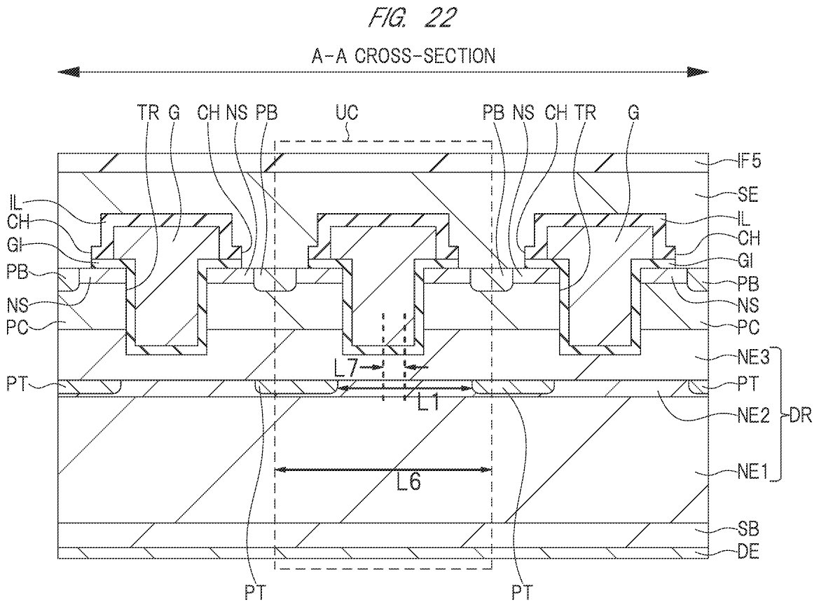

FIG. 20 shows a relationship between the ratio of the thickness of the n-type semiconductor layer NE2 (distance L4) to the thickness of the drift layer DR (distance L3) and the on-resistance. Herein, the thickness of the drift layer DR (distance L3) is the sum of the thicknesses of the n-type semiconductor layers NE1 to NE3. In addition, the distance L3 and the distance L4 shown in FIG. 20 correspond to the distance L3 and the distance L4 shown in FIG. 3. Herein, at each measurement point, the distance L1 is adjusted such that the breakdown voltage is constant at 1500 V. Also, the leftmost point (the point where the value of the horizontal axis is 0.00) is the point corresponding to the studied example.

As shown in FIG. 20, the on-resistance is reduced in the range where the value of distance L4/distance L3 is 0.02 to 0.13. Therefore, for example, when the thickness of the drift layer DR (distance L3) is 12 μm, the thickness of the n-type semiconductor layer NE2 (distance L4) is preferably in the range of 0.24 μm to 1.56 μm.

FIG. 21 shows a relationship between the ratio of the thickness of the n-type semiconductor layer NE2 (distance L4) to the thickness of the p-type impurity region PT (distance L5) and the on-resistance. Also, the distance L4 and the distance L5 shown in FIG. 21 correspond to the distance L4 and the distance L5 shown in FIG. 3. Herein, at each measurement point, the distance L1 is adjusted such that the breakdown voltage is constant at 1500 V. In addition, the leftmost point (the point where the value of the horizontal axis is 0.0) is the point corresponding to the studied example.

As shown in FIG. 21, the on-resistance is reduced in the range where the value of distance L4/distance L5 is 0.5 to 2.2. Also, a high effect can be obtained in the range where the value of the distance L4/distance L5 is 1.0 to 2.0, and a higher effect can be obtained in the range of 1.4 to 1.9. For example, when the thickness of the p-type impurity region PT (distance L5) is 0.4 μm, the thickness of the n-type semiconductor layer NE2 (distance L4) is preferably in the range of 0.2 μm to 0.88 μm, more preferably in the range of 0.4 μm to 0.8 μm, and still more preferably in the range of 0.56 μm to 0.76 μm.

As described above, in the present embodiment, by not only forming the n-type semiconductor layer NE2 just below the trench TR, but also setting the relationship of the respective components to an appropriate range, the performance of the semiconductor device can be further improved and the reliability of the semiconductor device can be further improved.

### Modification of First Embodiment

FIG. 22 shows a semiconductor device according to a modification of the first embodiment. In the following, the difference from the first embodiment will be mainly described.

In the first embodiment described above, when a center line is drawn in the thickness direction from the center of the gate electrode Gin a cross-section perpendicular to the Y direction, the two p-type impurity regions PT adjacent to each other are arranged to be symmetrical with respect to the center line.

Meanwhile, in the present modification, the two p-type impurity regions PT adjacent to each other are arranged to be asymmetrical with respect to the center line.

In FIG. 22, the distance of the deviation between the center line and the midpoint of the two p-type impurity regions PT adjacent to each other is represented as a distance L7. In other words, the center line and the center of the n-type semiconductor layer NE2 are separated by the distance L7.

Also, the width of the unit cell UC in the present modification is the same as the width of the unit cell UC in the first embodiment. Therefore, in the unit cell UC, the plane area and the volume of the p-type impurity region PT and the plane area and the volume of the n-type semiconductor layer NE2 are the same in the first embodiment and the present modification.

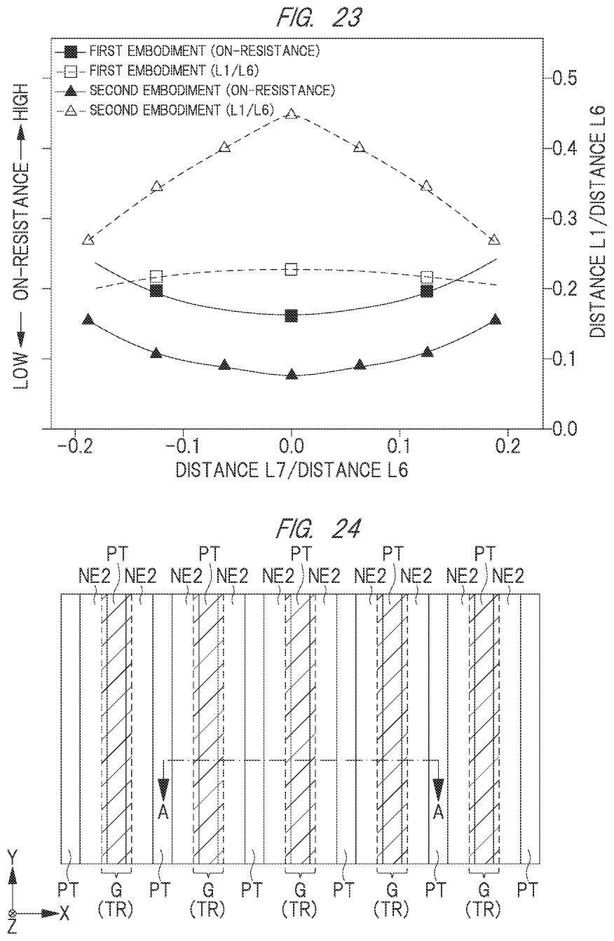

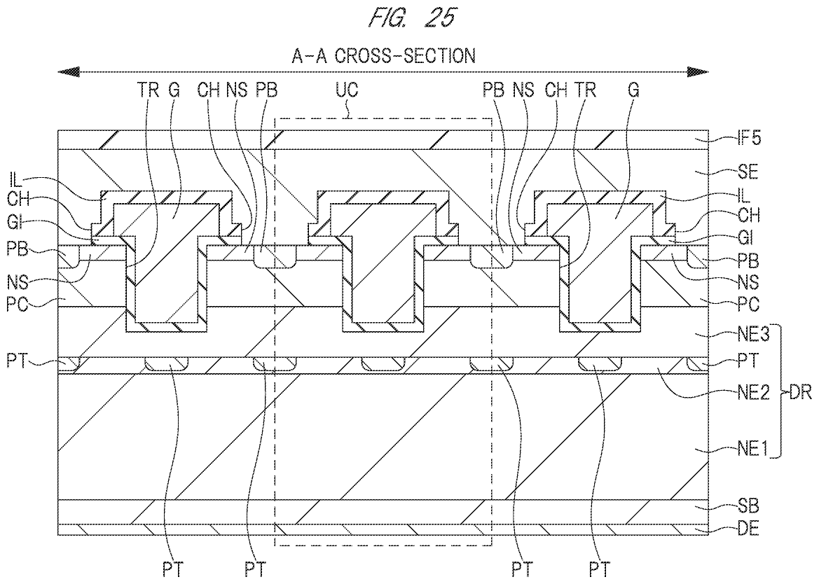

FIG. 23 is a graph chart showing a result of simulation by the inventors of the present invention, and FIG. 23 shows not only the result of the present modification but also the result of a modification of the second embodiment described later as a comparative object.

FIG. 23 shows a relationship between the ratio of the distance L7 to the width of the unit cell UC (distance L6) and the on-resistance with a solid line. Also, the point where the value of the horizontal axis is 0.0 is the point corresponding to the first embodiment, and is the point where the center line and the midpoint of the two p-type impurity regions PT adjacent to each other coincide with each other.

As shown in FIG. 23, the on-resistance is increased as the absolute value of distance L7/distance L6 becomes larger. According to the study by the inventors of the present invention, the value of the on-resistance required in the market can be retained when the absolute value of distance L7/distance L6 is equal to or smaller than ⅛ (0.125). In other words, ideally, it is most preferable that the two p-type impurity regions PT adjacent to each other are arranged to be symmetrical with respect to the center line as in the above-described first embodiment, but the performance of the semiconductor device can be maintained if the absolute value of distance L7/distance L6 is equal to or smaller than ⅛ (0.125) as in the present modification.

In FIG. 23, at each measurement point, the distance L1 is adjusted such that the breakdown voltage is constant at 1500 V. The broken line in FIG. 23 indicates a relationship between the ratio of the distance L7 to the width of the unit cell UC (distance L6) and the ratio of the distance between the p-type impurity regions PT (distance L1) to the width of the unit cell UC (distance L6). As shown in FIG. 23, when the absolute value of distance L7/distance L6 is increased, the value of distance L1/distance L6 is slightly reduced. Namely, the width of the p-type impurity region PT itself is slightly increased. As a result, the breakdown voltage can be kept constant even when the center line and the midpoint of the two p-type impurity regions PT adjacent to each other are deviated from each other.

### Second Embodiment

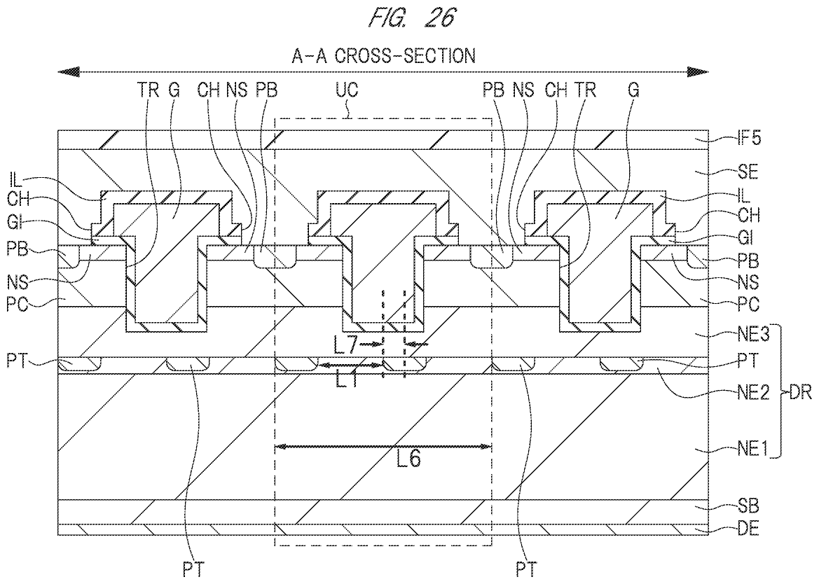

Hereinafter, a semiconductor device according to the second embodiment will be described with reference to FIGS. 24 and 25. FIG. 24 is a plan view of a principal part showing the same portion as that of FIG. 2 of the first embodiment, and FIG. 25 is a cross-sectional view taken along a line A-A in FIG. 24. In the following, the difference from the first embodiment will be mainly described.

In the first embodiment described above, the cycle of the arrangement of the p-type impurity regions PT is the same as the width of the unit cell UC (distance L6).

On the other hand, the cycle of the arrangement of the p-type impurity regions PT is an integer fraction of the width of the unit cell UC (distance L6). In FIG. 24 and FIG. 25, as an example of the cycle, the case where the cycle is one-half of the distance L6 is exemplified. Therefore, two p-type impurity regions PT are arranged in the unit cell UC.

In FIG. 24, the semiconductor device in which the p-type impurity region PT is arranged at the position overlapping with the gate electrode G formed in the trench TR in plan view is exemplified. In other words, as shown in FIG. 25, the p-type impurity region PT is formed just below a part of the gate electrode G formed in the trench TR. In addition, the plurality of p-type impurity regions PT are arranged so as to be spaced apart from each other. Therefore, in the second embodiment, the breakdown voltage of the power transistor can be further improved than the first embodiment.

In the second embodiment as well, the n-type semiconductor layer NE2 may be formed just below at least a part of the gate electrode G formed in the trench TR as in the first embodiment. In particular, the n-type semiconductor layer NE2 may be formed just below at least one of the two corners of the gate electrode G formed in the trench TR. However, these features are not indispensable in the second embodiment, and the p-type impurity region PT may be formed just below the entire gate electrode G formed in the trench TR.

In addition, as described above, by merely forming the p-type impurity region PT just below the gate electrode G formed in the trench TR, the breakdown voltage of the power transistor is improved, but the on-resistance is increased. Therefore, in the second embodiment, the width of each p-type impurity region PT itself is reduced to increase the area and volume of the n-type semiconductor layer NE2 in the unit cell UC as compared with the first embodiment.

Also, as in the first embodiment, when a center line is drawn in the thickness direction from the center of the gate electrode G in a cross-section perpendicular to the Y direction, it is most preferable that these p-type impurity regions PT are arranged to be symmetrical with respect to the center line.

FIG. 15 a graph chart showing a relationship between the on-resistance and the breakdown voltage of the power transistor in the case where the distance L1 between the p-type impurity regions PT adjacent to each other is changed. As can be seen from FIG. 15, the semiconductor device according to the second embodiment is superior not only to the semiconductor device of the studied example but also to the semiconductor device of the first embodiment in both of the on-resistance and the breakdown voltage of the power transistor.

Note that the manufacturing method of the second embodiment differs from that of the first embodiment in the pattern of the insulating film IF1 which is the mask for forming the p-type impurity region PT described with reference to FIG. 5, but is the same as that of the first embodiment except for it.

Also, in the second embodiment, the case where the cycle of the arrangement of the p-type impurity regions PT is one-half of the width of the unit cell UC (distance L6) is exemplified, but the cycle of the arrangement of the p-type impurity regions PT may be other values such as one-third of the distance L6.

### Modification of Second Embodiment

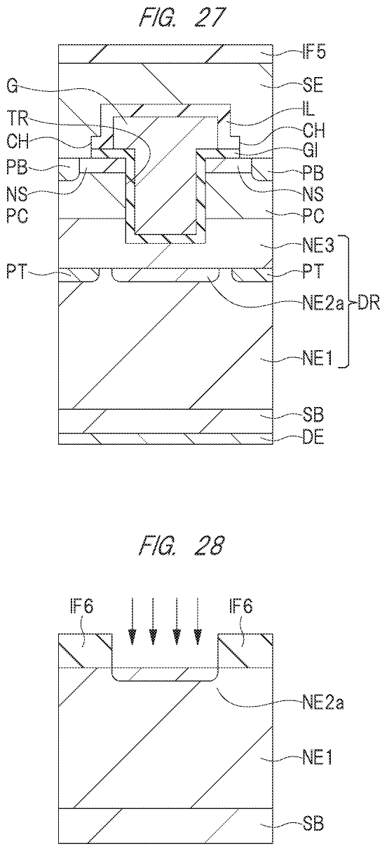

FIG. 26 shows a semiconductor device according to a modification of the second embodiment. In the following, the difference from the second embodiment will be mainly described.

In the present modification, when a center line is drawn in the thickness direction from the center of the gate electrode Gin a cross-section perpendicular to the Y direction, the p-type impurity regions PT are arranged to be asymmetrical with respect to the center line as in the modification of the first embodiment. Also, in the present modification, the distance of the deviation between the center line and the center of the p-type impurity region PT located just below the trench TR is represented as the distance L7. In other words, the center line and the center of the p-type impurity region PT located just below the trench TR are separated by the distance L7.

FIG. 23 shows a relationship between the ratio of the distance L7 to the width of the unit cell UC (distance L6) and the on-resistance by a solid line. Also, the point where the value of the horizontal axis is 0.0 is the point corresponding to the second embodiment, and is the point where the center line and the center of the p-type impurity region PT located just below the trench TR coincide with each other.

As indicated by the solid line in FIG. 23, the on-resistance increases as the absolute value of distance L7/distance L6 becomes larger. However, as compared with the first embodiment, the increase of the on-resistance is suppressed in the second embodiment.

Also, in the second embodiment and the present modification, the case where the cycle of the arrangement of the p-type impurity regions PT is one-half of the width of the unit cell UC (distance L6) is exemplified. Therefore, the broken line in FIG. 23 indicates the relationship between the ratio of the distance L7 to the width of the unit cell UC (distance L6) and the ratio of the double value of the distance between the p-type impurity regions PT (distance L1) to the width of the unit cell UC (distance L6). When the absolute value of distance L7/distance L6 is increased, it is necessary to make the width of the p-type impurity region PT itself smaller than that of the first embodiment. Accordingly, even when the center line and the center of the p-type impurity region PT located just below the trench TR are deviated from each other, the breakdown voltage can be kept constant.

### Third Embodiment

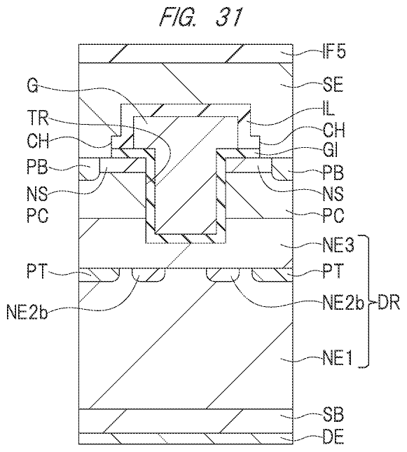

Hereinafter, a semiconductor device according to the third embodiment will be described with reference to FIGS. 27 and 30. In the following, the difference from the first embodiment will be mainly described. FIGS. 27 to 30 show only the unit cell UC.

In the first embodiment described above, the n-type semiconductor layer NE2 is formed over the entire upper surface of the n-type semiconductor layer NE1 by the epitaxial growth method, and the p-type impurity region PT is selectively formed in the n-type semiconductor layer NE2 by the ion implantation method. Therefore, the n-type semiconductor layer NE2 is in contact with the p-type impurity region PT.

In the third embodiment, as shown in FIG. 27, it is not always necessary that an n-type semiconductor layer NE2a is in contact with the p-type impurity region PT, and the n-type semiconductor layer NE2a may be arranged to be separated from the p-type impurity region PT. When both are separated from each other, a part of the n-type semiconductor layer NE1 is present between the p-type impurity region PT and the n-type semiconductor layer NE2a. Namely, the n-type semiconductor layer NE2a is selectively formed in a part of the region between the p-type impurity regions PT adjacent to each other.

In the third embodiment as well, the n-type semiconductor layer NE2a as the high-concentration n-type impurity region is formed just below at least a part of the gate electrode G formed in the trench TR as in the first embodiment. In particular, the n-type semiconductor layer NE2a is formed just below at least one of the two corners of the trench TR. Therefore, it is possible to reduce the on-resistance of the power transistor. However, the n-type semiconductor layer NE1 whose impurity concentration is lower than that of the n-type semiconductor layer NE2a is present in the region distant from the position just below the gate electrode G. Namely, the n-type semiconductor layer NE2a is selectively formed only in the region having high current density to be the main path of the current path, and the n-type semiconductor layer NE1 is present in the region having low current density. Therefore, it is possible to improve the breakdown voltage while effectively reducing the on-resistance.

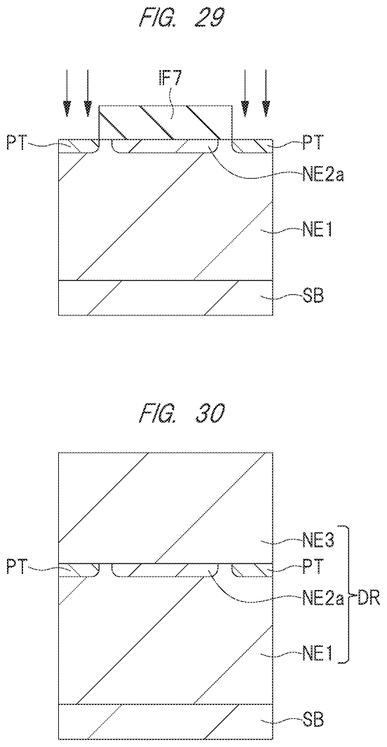

FIGS. 28 to 30 show a manufacturing method of the semiconductor device according to the third embodiment.

First, as shown in FIG. 28, an insulating film IF6 made of, for example, silicon oxide is formed over the n-type semiconductor layer NE1 by, for example, the CVD method. Next, the insulating film IF6 is patterned by the photolithography method and the etching process. Then, by performing ion implantation with using the patterned insulating film IF6 as a mask, the n-type semiconductor layer NE2a is formed as a high-concentration n-type impurity region in the n-type semiconductor layer NE1. The ion implantation may be performed in one step or plural steps. In the case of the ion implantation performed in plural steps, the peak position of each impurity concentration may be adjusted by changing the implantation energy. Thereafter, the insulating film IF6 is removed by the wet etching process using solution containing hydrofluoric acid or the like.

Next, as shown in FIG. 29, an insulating film IF7 made of, for example, silicon oxide is formed over the n-type semiconductor layer NE1 and the n-type semiconductor layer NE2a by, for example, the CVD method. Next, the insulating film IF7 is patterned by the photolithography method and the etching process. Then, by performing ion implantation with using the patterned insulating film IF7 as a mask, the p-type impurity region PT is formed in the n-type semiconductor layer NE1. Thereafter, the insulating film IF7 is removed by the wet etching process using solution containing hydrofluoric acid or the like.

In the third embodiment, the example in which the n-type semiconductor layer NE2a is first formed, and then the p-type impurity region PT is formed thereafter has been shown, but the order of formation may be reversed.

Next, as shown in FIG. 30, the n-type semiconductor layer NE3 is formed over the n-type semiconductor layer NE1, the n-type semiconductor layer NE2a, and the p-type impurity region PT by the epitaxial growth method. In this manner, the drift layer DR including the n-type semiconductor layer NE1, the n-type semiconductor layer NE2a, the n-type semiconductor layer NE3, and the p-type impurity region PT is formed.

Thereafter, the semiconductor device shown in FIG. 27 is manufactured through the same manufacturing process as the first embodiment.

As described above, in the third embodiment, the n-type semiconductor layer NE2a and the p-type impurity region PT are formed by performing the ion implantation, but the impurity concentration of the n-type semiconductor layer NE2a and the impurity concentration of the p-type impurity region PT are the same as the impurity concentration of the n-type semiconductor layer NE2 and the impurity concentration of the p-type impurity region PT in the first embodiment, respectively.

In addition, since the ion implantation is used instead of the epitaxial growth method in the third embodiment, it is possible to achieve an effect of being able to easily adjust the thickness of the n-type semiconductor layer NE2a (distance L4) and an effect of being able to easily adjust the impurity profile in the n-type semiconductor layer NE2a. Namely, the n-type semiconductor layer NE2a is a layer having the impurity concentration higher than the n-type semiconductor layer NE1 and the n-type semiconductor layer NE3. However, for example, when the epitaxial growth method is used, the gradient of the impurity concentration becomes steep at the interface between the n-type semiconductor layer NE2a and the n-type semiconductor layer NE3. Therefore, the electric field near the interface changes rapidly, and there is a fear for the reduction in the breakdown voltage. The similar problem occurs also at the interface between the n-type semiconductor layer NE2a and the n-type semiconductor layer NE1. In the third embodiment, it is possible to adjust the impurity concentration by using the above-described ion implantation such that the gradient of the impurity concentration near the interfaces becomes moderate. Therefore, the reliability of the semiconductor device can be further improved.

Also, the technique described in the third embodiment may be applied to the modification of the first embodiment, the second embodiment, and the modification of the second embodiment described above.

### Modification of Third Embodiment

FIG. 31 shows a semiconductor device according to a modification of the third embodiment. In the following, the difference from the third embodiment will be mainly described.

In the present modification as well, an n-type semiconductor layer NE2b is formed by ion implantation as in the third embodiment.

The n-type semiconductor layer NE2a formed between the p-type impurity regions PT adjacent to each other in the third embodiment described above is separated into two portions. Therefore, in the present modification, the two n-type semiconductor layers NE2b are formed as two separated portions as shown in FIG. 31. Therefore, the low-concentration n-type semiconductor layer NE1 is present between the two n-type semiconductor layers NE2b.

Also, the two n-type semiconductor layers NE2b are formed just below the two corners of the gate electrode G formed in the trench TR, respectively. Namely, the two n-type semiconductor layers NE2b are arranged in the region having the highest current density. Accordingly, as compared with the third embodiment, though the on-resistance is slightly higher, the breakdown voltage can be further improved.

Further, although the two n-type semiconductor layers NE2b are exemplified in the present modification, three or more n-type semiconductor layers NE2b may be arranged. Namely, it is also possible to form the plurality of n-type semiconductor layers NE2b as the structure in which the n-type semiconductor layer NE2a is separated into a plurality of portions in the region between the p-type impurity regions PT adjacent to each other.

Note that the manufacturing method of the n-type semiconductor layer NE2b differs from that of the third embodiment in the pattern of the insulating film IF6 described with reference to FIG. 28, but is the same as that of the third embodiment except for it.

### Fourth Embodiment

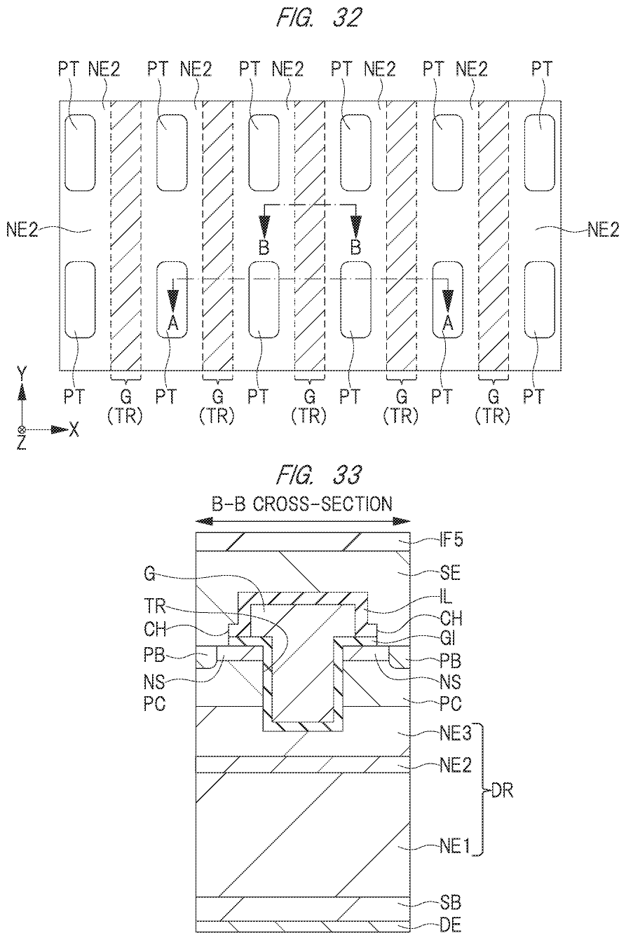

Hereinafter, a semiconductor device according to the fourth embodiment will be described with reference to FIGS. 32 and 33. FIG. 32 is a plan view of a principal part showing the same portion as that of FIG. 2 of the first embodiment, and FIG. 33 is a cross-sectional view taken along a line B-B in FIG. 32. Note that the cross-sectional view taken along a line A-A in FIG. 32 is the same as FIG. 3. In the following, the difference from the first embodiment will be mainly described.

In the first embodiment described above, the p-type impurity region PT is continuously formed so as to extend in the Y direction, similarly to the trench TR and the gate electrode G in plan view. Namely, the p-type impurity regions PT are formed in stripe shape in plan view.

In the fourth embodiment, as shown in FIG. 32, the p-type impurity region PT is divided in the Y direction in plan view, and the plurality of p-type impurity regions PT are formed to be spaced apart from each other. Namely, in plan view, the plurality of p-type impurity regions PT are separated in the Y direction and the X direction, and are formed into a shape of plurality of islands.

Also, as shown in FIG. 33, in the B-B cross-section, the p-type impurity region PT is not formed in the n-type semiconductor layer NE2. In other words, the n-type semiconductor layer NE2 is formed between the p-type impurity regions PT adjacent to each other in the Y direction.

As described above, the p-type impurity region PT may be formed discontinuously in the Y direction. In this case, however, the breakdown voltage is likely to slightly decrease as compared with the first embodiment.

However, as described above in the first embodiment and the second embodiment with reference to FIG. 15, the on-resistance and the breakdown voltage of the power transistor can be adjusted by the distance L1 between each of the p-type impurity regions PT in the X direction. Therefore, the adjustment to the desired breakdown voltage is possible by discontinuously forming the p-type impurity region PT in the Y direction in the state where the breakdown voltage is improved by reducing the distance L1 between the p-type impurity regions PT in the X direction. As described above, by using the technique disclosed in the fourth embodiment, the degree of freedom in the design for adjusting the breakdown voltage can be improved.

Note that the manufacturing method of the fourth embodiment differs from that of the first embodiment in the pattern of the insulating film IF1 which is the mask for forming the p-type impurity region PT described with reference to FIG. 5, but is the same as that of the first embodiment except for it.

### Modification of Fourth Embodiment

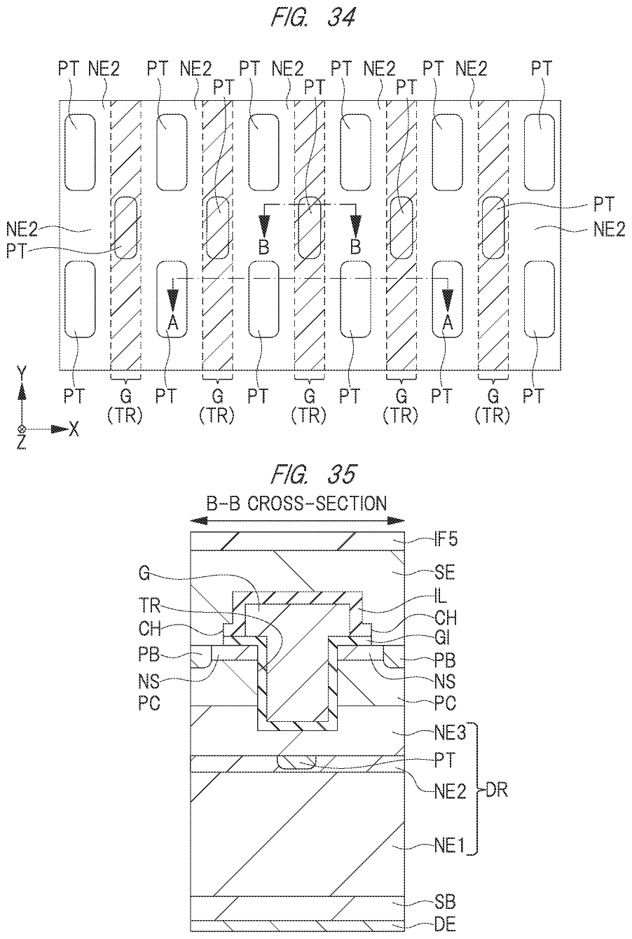

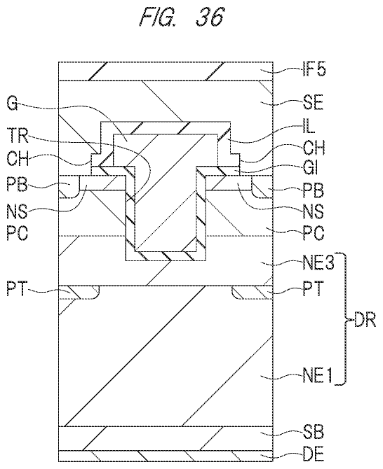

Hereinafter, a semiconductor device according to a modification of the fourth embodiment will be described with reference to FIGS. 34 and 35. FIG. 34 is a plan view of a principal part showing the same portion as that of FIG. 32 of the fourth embodiment, and FIG. 35 is a cross-sectional view taken along a line B-B in FIG. 34. Note that the cross-sectional view taken along a line A-A in FIG. 34 is the same as FIG. 3. In the following, the difference from the fourth embodiment will be mainly described.

As shown in FIG. 34, in the present modification as well, the p-type impurity region PT is discontinuously formed in the Y direction as in the fourth embodiment.

However, as shown in FIG. 35, in the B-B cross-section, the p-type impurity region PT is formed just below a part of the gate electrode G formed in the trench TR. Therefore, in the present modification, the structure of the A-A cross-section in FIG. 3 and the structure of the B-B cross-section in FIG. 35 are alternately formed in the Y direction. Accordingly, as shown in FIG. 34, the plurality of p-type impurity regions PT are arranged in a zigzag manner in plan view. In other words, the plurality of p-type impurity regions PT located just below a part of the trench TR are formed so as to be spaced apart from each other in the regions not adjacent to the other p-type impurity regions PT in the X direction.

As described above, by adopting the structure in which the p-type impurity region PT is arranged also just below a part of the gate electrode G formed in the trench TR, it is possible to improve the breakdown voltage more easily as compared with the fourth embodiment.

In the foregoing, the invention made by the inventors of the present invention has been concretely described based on the embodiments. However, the present invention is not limited to the foregoing embodiments and various modifications can be made within the scope of the present invention.

For example, the first to fourth embodiments have been described above on the assumption that the trench-gate power transistor is the n-type MOSFET, but the technique of the first to fourth embodiments described above may be applied to a p-type MOSFET. Specifically, the p-type MOSFET can be manufactured by reversing the conductivity type of the respective components described in the first to fourth embodiments.

In addition, the first to fourth embodiments have been described above on the assumption that the trench-gate power transistor is the MOSFET, but it is also possible to apply the trench-gate power transistor to an IGBT (Insulated Gate Bipolar Transistor).

In addition, some of the contents described in the above embodiments will be described below.

[Appendix 1]

A semiconductor device comprising:

a semiconductor substrate configured to contain silicon and carbon;

a first semiconductor layer of a first conductivity type formed over an upper surface of the semiconductor substrate;

a third semiconductor layer of the first conductivity type formed over the first semiconductor layer;

a second semiconductor layer of the first conductivity type formed between the first semiconductor layer and the third semiconductor layer;

a plurality of first impurity regions which are formed between the first semiconductor layer and the third semiconductor layer, have a second conductivity type opposite to the first conductivity type, and are formed so as to interpose the second semiconductor layer in plan view;

a second impurity region of the second conductivity type formed in the third semiconductor layer;

a third impurity region of the first conductivity type formed in the first impurity region;

a trench which penetrates the second impurity region and the third impurity region and reaches the third semiconductor layer;

a gate insulating film formed in the trench; and

a gate electrode buried in the trench with the gate insulating film interposed therebetween,

wherein an impurity concentration of the second semiconductor layer is higher than an impurity concentration of the first semiconductor layer and an impurity concentration of the third semiconductor layer,

the trench and the gate electrode extend in a first direction in plan view,

a plurality of the gate electrodes are formed adjacent to each other in a second direction, and

when a center line is drawn in a thickness direction from a center of the gate electrode in a cross-section perpendicular to the first direction and a distance connecting the center lines of the two gate electrodes adjacent in the second direction is defined as L6, the plurality of first impurity regions are formed in a cycle of a fraction of an integer of the L6.

[Appendix 2]

The semiconductor device according to Appendix 1,

wherein the cycle is one-half of the L6.

[Appendix 3]

The semiconductor device according to Appendix 1,

wherein the second semiconductor layer located between the first impurity regions adjacent to each other overlaps with at least a part of the gate electrode buried in the trench in a plan view.

[Appendix 4]

The semiconductor device according to Appendix 1,

wherein one of the plurality of first impurity regions is formed just below the entire gate electrode buried in the trench.

What is claimed is:

1. A manufacturing method of a semiconductor device, comprising the steps of:
(a) preparing a semiconductor substrate configured to contain silicon and carbon, a first semiconductor layer of a first conductivity type formed over an upper surface of the semiconductor substrate, and a second semiconductor layer of the first conductivity type formed over the first semiconductor layer;
(b) selectively forming a first impurity region and a second impurity region of a second conductivity type opposite to the first conductivity type in the second semiconductor layer so as to be spaced apart from each other;
(c) forming a third semiconductor layer of the first conductivity type over the second semiconductor layer, the first impurity region, and the second impurity region;
(d) forming a third impurity region of the second conductivity type in the third semiconductor layer;
(e) forming a fourth impurity region of the first conductivity type in the third impurity region;
(f) forming a trench which penetrates the fourth impurity region and the third impurity region and reaches the third semiconductor layer;
(g) forming a gate insulating film in the trench; and
(h) forming a gate electrode so as to fill the trench with the gate insulating film interposed therebetween,
wherein an impurity concentration of the second semiconductor layer is higher than an impurity concentration of the first semiconductor layer and an impurity concentration of the third semiconductor layer.

2. The manufacturing method of the semiconductor device according to claim 1, wherein the second semiconductor layer located between the first impurity region and the second impurity region overlaps with at least a part of the gate electrode buried in the trench in plan view.

3. The manufacturing method of the semiconductor device according to claim 2,
wherein, in the step (a), the second semiconductor layer is formed by epitaxial growth method, and
wherein, in the step (b), the first impurity region and the second impurity region are formed by ion implantation.

4. A manufacturing method of a semiconductor device, comprising the steps of:
(a) preparing a semiconductor substrate configured to contain silicon and carbon and a first semiconductor layer of a first conductivity type formed over an upper surface of the semiconductor substrate;
(b) selectively forming a second semiconductor layer of the first conductivity type in the first semiconductor layer;
(c) selectively forming a first impurity region and a second impurity region of a second conductivity type opposite to the first conductivity type in the first semiconductor layer so as to interpose the second semiconductor layer;
(d) forming a third semiconductor layer of the first conductivity type over the second semiconductor layer, the first impurity region, and the second impurity region;
(e) forming a third impurity region of the second conductivity type in the third semiconductor layer;
(f) forming a fourth impurity region of the first conductivity type in the third impurity region;
(g) forming a trench which penetrates the fourth impurity region and the third impurity region and reaches the third semiconductor layer;
(h) forming a gate insulating film in the trench; and
(i) forming a gate electrode so as to fill the trench with the gate insulating film interposed therebetween,
wherein an impurity concentration of the second semiconductor layer is higher than an impurity concentration of the first semiconductor layer and an impurity concentration of the third semiconductor layer.

5. The manufacturing method of the semiconductor device according to claim 4, wherein the second semiconductor layer located between the first impurity region and the second impurity region overlaps with at least a part of the gate electrode buried in the trench in plan view.

6. The manufacturing method of the semiconductor device according to claim 5, wherein, in the step (b), the second semiconductor layer is formed by ion implantation and a plurality of the second semiconductor layers are formed so as to be spaced apart from each other in the first semiconductor layer between the first impurity region and the second impurity region.
